(19) United States
(12) Patent Application Publication
(10) Pub. No.: US 2025/0087479 A1
(43) Pub. Date: Mar. 13, 2025

(54) ETCHING METHODS AND PATTERNED SUBSTRATES MADE USING SAID METHODS

(71) Applicant: Ohio State Innovation Foundation, Columbus, OH (US)

(72) Inventors: Siddharth Rajan, Columbus, OH (US); Sheikh Ifatur Rahman, Columbus, OH (US); Ashok Dheenan, Columbus, OH (US); Nathan Wriedt, Columbus, OH (US)

(21) Appl. No.: 18/826,539

(22) Filed: Sep. 6, 2024

Related U.S. Application Data
(60) Provisional application No. 63/537,009, filed on Sep. 7, 2023.

(51) Int. Cl. H01L 21/02; H01L 21/311

(52) U.S. Cl. CPC H01L 21/02241; H01L 21/31122

(57) ABSTRACT

Disclosed herein are etching methods, patterned substrates made using said methods, and methods of use of said patterned substrates. For example, described herein are methods comprising: oxidizing at least a portion of a surface of a substrate comprising a group III-V compound, thereby forming an oxidized layer at said portion of the surface; and etching the oxidized layer by exposing the oxidized layer to an etchant; wherein: the group III-V compound comprises one or more group III elements (e.g., Al, Ga, In, B, Sc, Y, or a combination thereof) and a group V element (e.g., N, As, or Sb); the etchant comprises at least one of the group III elements; and the etchant removes oxides by the etchant reacting with the oxide to form a suboxide, which desorbs from the surface.

### CROSS-REFERENCE TO RELATED APPLICATIONS

This application claims the benefit of priority to U.S. Provisional Application No. 63/537,009 filed Sep. 7, 2023, which is hereby incorporated herein by reference in its entirety.

### STATEMENT OF GOVERNMENT SUPPORT

This invention was made with government support under Grant/Contract No. DE-NA000392 awarded by DOE/NNSA and Grant/Contract No. FA9550-18-1-0479 awarded by AFOSR GAME MURI. The government has certain rights in the invention.

### BACKGROUND

Devices with improved properties are needed. For example, the demand for group III-V based semiconductor electronic devices has been on the rise. However, the fabrication of such group II-V-based devices often requires the selective removal of material through an etching process. Standard wet etching processes can leave the etched surface with unwanted impurities and are difficult to control precisely. In contrast, dry etching processes using reactive ion etching can provide better process control. However, the bombardment of the material with ions results in subsurface damage and roughened surface morphology that can negatively impact device performance. Other drawbacks include the formation of angled sidewalls and imprecise etch depths, making it difficult to produce highly scaled features. Additionally, the quality of any regrowth material on the etched surface is degraded due to plasma damage. Improved etching methods are needed. The compositions, methods, and devices discussed herein addresses these and other needs.

### SUMMARY

In accordance with the purposes of the disclosed compositions, methods, and devices as embodied and broadly described herein, the disclosed subject matter relates to etching methods, patterned substrates made using said methods, and methods of use of said patterned substrates.

For example, described herein are methods comprising: oxidizing at least a portion of a surface of a substrate comprising a group III-V compound, thereby forming an oxidized layer at said portion of the surface; and etching the oxidized layer by exposing the oxidized layer to an etchant. The group III-V compound comprises one or more group III elements (e.g., Al, Ga, In, B, Sc, Y, or a combination thereof) and a group V element (e.g., N, As, or Sb). The etchant comprises at least one of the group III elements. The etchant removes oxides by the etchant reacting with the oxide to form a suboxide, which desorbs from the surface.

In some examples, the one or more group III elements are selected from the group consisting of Al, Ga, In, B, Sc, Y, and combinations thereof; and the group V element is selected from the group consisting of N, As, and Sb.

In some examples, the group III-V compound comprises InₓGa₁₋ₓN, AlₓGa₁₋ₓN, ScₓGa₁₋ₓ N, YₓGa₁₋ₓN, AlₓGa₁₋ₓAs, InₓGa₁₋ₓAs, AlₓGa₁₋ₓSb, InₓGa₁₋ₓSb, or a combination thereof, wherein each x independently is from 0 to 1.

In some examples, the group III-V compound comprises GaN, InN, AlN, ScN, YN, GaAs, AlAs, InAs, GaSb, InSb, AlSb, or a combination thereof.

In some examples, the group III-V compound comprises AlₓGa₁₋ₓN, wherein x is from 0 to 1.

In some examples, the group III-V compound comprises AlₓGa₁₋ₓN, and the etchant comprises Al, Ga, or a combination thereof.

Also disclosed herein are methods comprising: oxidizing at least a portion of a surface of a substrate comprising AlₓGa₁₋ₓN, thereby forming an oxidized layer at said portion of the surface; and etching the oxidized layer by exposing the oxidized layer to an etchant; wherein the etchant comprises Al, Ga, or a combination thereof; and wherein the etchant removes oxides by the etchant reacting with the oxide comprising the etchant to form a suboxide, which desorbs from the surface.

In some examples, when x=1, the etchant comprises Al; when x=0, the etchant comprises Ga; and when 0<x<1, the etchant comprises Al, Ga, or a combination thereof.

Also disclosed herein are methods comprising: oxidizing at least a portion of a surface of a substrate comprising AlₓGa₁₋ₓN, thereby forming an oxidized layer at said portion of the surface; and etching the oxidized layer by exposing the oxidized layer to an etchant; wherein: when x=1, the etchant comprises Al; when x=0, the etchant comprises Ga; and when 0<x<1, the etchant comprises Al, Ga, or a combination thereof; wherein the etchant removes oxides comprising said etchant (e.g., Al etches aluminum oxides, Ga etches gallium oxides) by the etchant reacting with the oxide comprising the etchant to form a suboxide, which desorbs from the surface.

In some examples, the oxidized layer comprises an oxidized monolayer.

In some examples, oxidizing said portion comprises thermal oxidation, plasma oxidation, exposing said portion to an oxidizing agent (e.g., water, active oxygen, hydrogen peroxide, etc.), or a combination thereof.

In some examples, oxidizing said portion comprises thermal oxidation, plasma oxidation, or a combination thereof.

In some examples, the portion of the substrate is oxidized for a first amount of time. In some examples, the first amount of time is from 1 millisecond (ms) to 10 hours.

In some examples, the oxidized layer is exposed to the etchant for a second amount of time. In some examples, the second amount of time is from millisecond (ms) to 10 hours.

In some examples, the first amount of time and/or the second amount of time are controlled, for example, by opening and/or closing one or more shutters.

In some examples, the first amount of time and/or the second amount of time are selected to achieve a desired result, such as a desired etch depth.

In some examples, exposing the oxidized layer to the etchant comprises exposing the oxidized layer to a compound comprising the etchant, an atomic flux of the etchant, or a combination thereof.

In some examples, exposing the oxidized layer to the etchant comprises exposing the oxidized layer to a compound comprising the etchant. In some examples, the compound comprising the etchant undergoes decomposition to deposit the etchant on the oxidized layer.

In some examples, exposing the oxidized layer to the etchant comprises using an atomic flux of the etchant (e.g., an atomic flux of Al and/or Ga).

In some examples, the substrate further comprises a mask disposed on the surface thereof, wherein the mask covers a first portion of the surface of the substrate and does not cover a second portion of the surface of the substrate, wherein the second portion of the substrate is the portion oxidized by the method. In some examples, the method further comprises disposing the mask on the surface of the substrate.

In some examples, the substrate further comprise an etch stop layer, the etch stop layer comprising a composition that is not susceptible to etching by the etchant.

In some examples, the method is performed in an ultra-high vacuum environment.

In some examples, the method further comprises rotating the substrate during the methods, for example to improve uniformity of the oxidation and/or etching.

In some examples, the method further comprises heating the substrate at a temperature during the etching, wherein the temperature is selected to improve the etching. In some examples, the temperature is from 400° C. to 2000° C.

In some examples, the substrate comprises GaN, and the etchant comprises Ga. In some examples, the substrate comprises Wurtzite Ga-polar or N-polar GaN.

In some examples, the substrate comprises AlN, and the etchant comprises Al.

In some examples, the method does not cause any other substantial damage to the substrate (e.g., substantially no damage to any subsurface of the substrate).

In some examples, the method further comprises repeating the method to thereby etch another layer. In some examples, the method further comprises selecting the number of cycles the method is repeated to thereby selectively etch a desired thickness of the substrate.

In some examples, the method further includes etching lateral sidewalls.

Also disclosed herein are methods for damage-free etching of GaN and AlGaN/AlN by alternating thermal/plasma oxidation and etching using Ga flux and Al flux respectively in the ultra-high vacuum environment, for example wherein the method comprises any of the methods described herein.

Also disclosed herein are methods for monolayer etching of GaN/AlGaN/AlN by using successive cycles of thermal/plasma oxidation and Ga and Al flux exposure respectively, for example wherein the method comprises any of the methods described herein.

Also disclosed herein are methods for fabricating sub-micron 3D structures in GaN/AlGaN/AlN like fins, trenches, and nanopillar with vertical sidewalls for GaN/AlGaN/AlN-based devices, for example wherein the method comprises any of the methods described herein.

Also disclosed herein are methods to obtain a controlled etch depth by using AlₓGa₁₋ₓN as an etch stop layer for Ga flux etching to etch only GaN films, for example wherein the method comprises any of the methods described herein.

Also disclosed herein are methods to obtain a precise etch depth as the etch depth can be directly controlled by number of cycles, for example wherein the method comprises any of the methods described herein.

Also disclosed herein are patterned substrates made by any of the methods disclosed herein. In some examples, the patterned substrate comprises a set of features extending from a surface of a substrate, and integrally formed therewith. In some examples, the set of features comprise sub-micron 3D structures. In some examples, the set of features have substantially vertical sidewalls. In some examples, the set of features comprises fins, trenches, pillars, or a combination thereof. In some examples, the patterned substrate has a regrowth pattern.

Also disclosed herein are methods of use of any of the patterned substrates described herein. In some examples, the method comprises using the patterned substrate in an electronic device, an optical device, a photonic device, an optoelectronic device, or a combination thereof. In some examples, the method comprises using the patterned substrate in an energy storage device. In some examples, the method comprises using the patterned substrate in a power device. In some examples, the method comprises using the patterned substrate in a diode. In some examples, the method comprises using the patterned substrate in a memory device.

Also disclosed herein are devices or articles of manufacture comprising any of the patterned substrates described herein. In some examples, the device or article comprises an electronic device, an optical device, a photonic device, an optoelectronic device, or a combination thereof. In some examples, the device or article comprises an energy storage device. In some examples, the device or article comprises a power device. In some examples, the device or article comprises a diode. In some examples, the device or article comprises a memory device.

Additional advantages of the disclosed compositions, devices, and methods will be set forth in part in the description which follows, and in part will be obvious from the description. The advantages of the disclosed compositions, devices, and methods will be realized and attained by means of the elements and combinations particularly pointed out in the appended claims. It is to be understood that both the foregoing general description and the following detailed description are exemplary and explanatory only and are not restrictive of the disclosed devices and methods, as claimed.

The details of one or more embodiments of the invention are set forth in the accompanying drawings and the description below. Other features, objects, and advantages of the invention will be apparent from the description and drawings, and from the claims.

### BRIEF DESCRIPTION OF THE FIGURES

The accompanying figures, which are incorporated in and constitute a part of this specification, illustrate several aspects of the disclosure, and together with the description, serve to explain the principles of the disclosure.

FIG. 1. Shutter control timing diagram for monolayer cyclic process (two cycles shown here).

FIG. 2. Method for vertical etching of GaN with monolayer controlled etch depth to create trenches using cyclic O₂ plasma and Ga flux exposure.

FIG. 3. Method for vertical etching of GaN with monolayer controlled etch depth to create fin/pillar structure using cyclic O₂ plasma and Ga flux exposure.

FIG. 4. Method for vertical etching of GaN.

FIG. 5. Example shutter conditions for the method shown in FIG. 4.

FIG. 6. Example shutter conditions for the method shown in FIG. 4.

FIG. 7. AFM results of etched and unetched GaN sample.

FIG. 8. Thickness estimate from AFM.

FIG. 9. Etched surface via AFM.

### DETAILED DESCRIPTION

The compositions, methods, and devices described herein may be understood more readily by reference to the following detailed description of specific aspects of the disclosed subject matter and the Examples included therein.

Before the present compositions, methods, and devices are disclosed and described, it is to be understood that the aspects described below are not limited to specific synthetic methods or specific reagents, as such may, of course, vary. It is also to be understood that the terminology used herein is for the purpose of describing particular aspects only and is not intended to be limiting.

Also, throughout this specification, various publications are referenced. The disclosures of these publications in their entireties are hereby incorporated by reference into this application in order to more fully describe the state of the art to which the disclosed matter pertains. The references disclosed are also individually and specifically incorporated by reference herein for the material contained in them that is discussed in the sentence in which the reference is relied upon.

In this specification and in the claims that follow, reference will be made to a number of terms, which shall be defined to have the following meanings.

Throughout the description and claims of this specification the word “comprise” and other forms of the word, such as “comprising” and “comprises,” means including but not limited to, and is not intended to exclude, for example, other additives, components, integers, or steps.

As used in the description and the appended claims, the singular forms “a,” “an,” and “the” include plural referents unless the context clearly dictates otherwise. Thus, for example, reference to “a composition” includes mixtures of two or more such compositions, reference to “an agent” includes mixtures of two or more such agents, reference to “the component” includes mixtures of two or more such components, and the like.

“Optional” or “optionally” means that the subsequently described event or circumstance can or cannot occur, and that the description includes instances where the event or circumstance occurs and instances where it does not.

Ranges can be expressed herein as from “about” one particular value, and/or to “about” another particular value. By “about” is meant within 5% of the value, e.g., within 4, 3, 2, or 1% of the value. When such a range is expressed, another aspect includes from the one particular value and/or to the other particular value. Similarly, when values are expressed as approximations, by use of the antecedent “about,” it will be understood that the particular value forms another aspect. It will be further understood that the endpoints of each of the ranges are significant both in relation to the other endpoint, and independently of the other endpoint.

Values can be expressed herein as an “average” value. “Average” generally refers to the statistical mean value.

By “substantially” is meant within 5%, e.g., within 4%, 3%, 2%, or 1%.

“Exemplary” means “an example of” and is not intended to convey an indication of a preferred or ideal embodiment. “Such as” is not used in a restrictive sense, but for explanatory purposes.

It is understood that throughout this specification the identifiers “first” and “second” are used solely to aid in distinguishing the various components and steps of the disclosed subject matter. The identifiers “first” and “second” are not intended to imply any particular order, amount, preference, or importance to the components or steps modified by these terms.

References in the specification and concluding claims to parts by weight of a particular element or component in a composition denotes the weight relationship between the element or component and any other elements or components in the composition or article for which a part by weight is expressed. Thus, in a compound containing 2 parts by weight of component X and 5 parts by weight component Y, X and Y are present at a weight ratio of 2:5, and are present in such ratio regardless of whether additional components are contained in the compound.

A weight percent (wt. %) of a component, unless specifically stated to the contrary, is based on the total weight of the formulation or composition in which the component is included.

The term “or combinations thereof”′ as used herein refers to all permutations and combinations of the listed items preceding the term. For example, “A, B, C, or combinations thereof” is intended to include at least one of: A, B, C, AB, AC, BC, or ABC, and if order is important in a particular context, also BA, CA, CB, CBA, BCA, ACB, BAC, or CAB. Continuing with this example, expressly included are combinations that contain repeats of one or more item or term, such as BB, AAA, AB, BBC, AAABCCCC, CBBAAA, CABABB, and so forth. The skilled artisan will understand that typically there is no limit on the number of items or terms in any combination, unless otherwise apparent from the context.

### Etching Methods

Disclosed herein are etching methods.

For example, disclosed herein are methods comprising oxidizing at least a portion of a surface of a substrate comprising a group III-V compound, thereby forming an oxidized layer at said portion of the surface; and etching the oxidized layer by exposing the oxidized layer to an etchant. The group III-V compound comprises one or more group III elements (e.g., Al, Ga, In, B, Sc, Y, or a combination thereof) and a group V element (e.g., N, As, or Sb). The etchant comprises at least one of the group III elements. The etchant removes oxides by the etchant reacting with the oxide to form a suboxide, which desorbs from the surface.

In some examples, the group III-V compound comprises one or more group III elements and a group V element, wherein the one or more group III elements are selected from the group consisting of Al, Ga, In, B, Sc, Y, and combinations thereof; and the group V element is selected from the group consisting of N, As, and Sb.

In some examples, the group III-V compound comprises InₓGa₁₋ₓN, AlₓGa₁₋ₓN, ScₓGa₁₋ₓ N, YₓGa₁₋ₓN, AlₓGa₁₋ₓAs, InₓGa₁₋ₓAs, AlₓGa₁₋ₓSb, InₓGa₁₋ₓSb, or a combination thereof, wherein each x independently is from 0 to 1.

In some examples, the group III-V compound comprises AlₓGa₁₋ₓN, wherein x is from 0 to 1.

For example, x can be 0 or more (e.g., 0.1 or more, 0.2 or more, 0.3 or more, 0.4 or more, 0.5 or more, 0.6 or more, 0.7 or more, or 0.8 or more). In some examples, x can be 1 or less (e.g., 0.9 or less, 0.8 or less, 0.7 or less, 0.6 or less, 0.5 or less, 0.4 or less, 0.3 or less, or 0.2 or less). The value of x can range from any of the minimum values described above to any of the maximum values described above. For example, x can be from 0 to 1 (e.g., from 0 to 0.5, from 0.5 to 1, from 0 to 0.2, from 0.2 to 0.4, from 0.4 to 0.6, from 0.6 to 0.8, from 0.8 to 1, from 0 to 0.8, from 0 to 0.6, from 0 to 0.4, from 0.2 to 1, from 0.4 to 1, from 0.6 to 1, from 0.1 to 0.9, or from 0.2 to 0.8). In some examples, x is 0. In some examples, x is 1.

In some examples, the group III-V compound comprises GaN, InN, AlN, ScN, YN, GaAs, AlAs, InAs, GaSb, InSb, AlSb, or a combination thereof.

In some examples, the group III-V compound comprises AlₓGa₁₋ₓN, and the etchant comprises Al, Ga, or a combination thereof.

For example, disclosed herein are methods comprising oxidizing at least a portion of a surface of a substrate comprising AlₓGa₁₋ₓN, thereby forming an oxidized layer at said portion of the surface; and etching the oxidized layer by exposing the oxidized layer to an etchant; wherein the etchant comprises Al, Ga, or a combination thereof; and wherein the etchant removes oxides by the etchant reacting with the oxide comprising the etchant to form a suboxide, which desorbs from the surface.

In some examples, the substrate comprises AlₓGa₁₋ₓN and, when x=1, the etchant comprises Al; when x=0, the etchant comprises Ga; and when 0<x<1, the etchant comprises Al, Ga, or a combination thereof.

For example, disclosed herein are methods comprising: oxidizing at least a portion of a surface of a substrate comprising AlₓGa₁₋ₓN, thereby forming an oxidized layer at said portion of the surface; and etching the oxidized layer by exposing the oxidized layer to an etchant; wherein: when x=1, the etchant comprises Al; when x=0, the etchant comprises Ga; and when 0<x<1, the etchant comprises Al, Ga, or a combination thereof; wherein the etchant removes oxides comprising said etchant (e.g., Al etches aluminum oxides, Ga etches gallium oxides) by the etchant reacting with the oxide comprising the etchant to form a suboxide, which desorbs from the surface.

In some examples, the oxidized layer comprises an oxidized monolayer.

In some examples, oxidizing said portion comprises thermal oxidation, plasma oxidation, exposing said portion to an oxidizing agent (e.g., water, active oxygen, hydrogen peroxide, etc.), or a combination thereof. In some examples, oxidizing said portion comprises thermal oxidation, plasma oxidation, or a combination thereof.

In some examples, the portion of the substrate is oxidized for a first amount of time. The first amount of time can, for example, be 1 millisecond or more (e.g., 5 milliseconds or more, 10 milliseconds or more, 50 milliseconds or more, 100 milliseconds or more, 500 milliseconds or more, 1 second or more, 5 seconds or more, 10 seconds or more, 30 seconds or more, 1 minute or more, 5 minutes or more, 10 minutes or more, 30 minutes or more, 1 hour or more, or 5 hours or more). In some examples, the first amount of time is 10 hours or less (e.g., 5 hours or less, 1 hour or less, 30 minutes or less, 10 minutes or less, 5 minutes or less, 1 minute or less, 30 seconds or less, 10 seconds or less, 5 seconds or less, 1 second or less, 500 milliseconds or less, 100 milliseconds or less, 50 milliseconds or less, 10 milliseconds or less, or 5 milliseconds or less. The first amount of time can range from any of the minimum values described above to any of the maximum values described above. For example, the first amount of time can be from 1 millisecond to 10 hours (e.g., from 1 millisecond to 1 minute, from 1 minute to 10 hours, from 1 millisecond to 1 second, from 1 second to 1 minute, from 1 minute to 1 hour, from 1 hour to 10 hours, from 1 millisecond to 1 hour, from 1 second to 10 hours, or from 1 second to 1 hour).

In some examples, the oxidized layer is exposed to the etchant for a second amount of time. The second amount of time can, for example, be 1 millisecond or more (e.g., 5 milliseconds or more, 10 milliseconds or more, 50 milliseconds or more, 100 milliseconds or more, 500 milliseconds or more, 1 second or more, 5 seconds or more, 10 seconds or more, 30 seconds or more, 1 minute or more, 5 minutes or more, 10 minutes or more, 30 minutes or more, 1 hour or more, or 5 hours or more). In some examples, the second amount of time is 10 hours or less (e.g., 5 hours or less, 1 hour or less, 30 minutes or less, 10 minutes or less, 5 minutes or less, 1 minute or less, 30 seconds or less, 10 seconds or less, 5 seconds or less, 1 second or less, 500 milliseconds or less, 100 milliseconds or less, 50 milliseconds or less, 10 milliseconds or less, or 5 milliseconds or less. The second amount of time can range from any of the minimum values described above to any of the maximum values described above. For example, the second amount of time can be from 1 millisecond to 10 hours (e.g., from 1 millisecond to 1 minute, from 1 minute to 10 hours, from 1 millisecond to 1 second, from 1 second to 1 minute, from 1 minute to 1 hour, from 1 hour to 10 hours, from 1 millisecond to 1 hour, from 1 second to 10 hours, or from 1 second to 1 hour). In some examples, the first amount of time and/or the second amount of time are controlled, for example, by opening and/or closing one or more shutters.

In some examples, the first amount of time and/or the second amount of time are selected to achieve a desired result, such as a desired etch depth.

In some examples, exposing the oxidized layer to the etchant comprises exposing the oxidized layer to a compound comprising the etchant, an atomic flux of the etchant, or a combination thereof.

In some examples, exposing the oxidized layer to the etchant comprises exposing the oxidized layer to a compound comprising the etchant. In some examples, the compound comprising the etchant undergoes decomposition to deposit the etchant on the oxidized layer (for example as described by Abishek, et al. “Demonstration of MOCVD based in situ etching of β-Ga₂O₃ using TEGa.” Journal of Applied Physics 135.7 (2024), which is hereby incorporated herein by reference for its description thereof).

In some examples, exposing the oxidized layer to the etchant comprises using an atomic flux of the etchant (e.g., an atomic flux of Al and/or Ga).

In some examples, the substrate further comprises a mask disposed on the surface thereof, wherein the mask covers a first portion of the surface of the substrate and does not cover a second portion of the surface of the substrate, wherein the second portion of the substrate is the portion oxidized by the method. In some examples, the method further comprises disposing the mask on the surface of the substrate.

In some examples, the substrate further comprise an etch stop layer, the etch stop layer comprising a composition that is not susceptible to etching by the etchant. For example AlGaN alloy thin films with Al mole fraction of 30% would lead to an aluminum oxide top layer which would not be etched by Ga.

In some examples, the method is performed in an ultra-high vacuum environment.

In some examples, the method further comprises rotating the substrate during the methods, for example to improve uniformity of the oxidation and/or etching.

In some examples, the method further comprises heating the substrate at a temperature during the etching, wherein the temperature is selected to improve the etching. The temperature can, for example, be 400° C. or more (e.g., 500° C. or more, 750° C. or more, 1000° C. or more, 1250° C. or more, 1500° C. or more, or 1750° C. or more). In some examples, the temperature can be 2000° C. or less (e.g., 1750° C. or less, 1500° C. or less, 1250° C. or less, 1000° C. or less, 750° C. or less, or 500° C. or less). The temperature can range from any of the minimum values described above to any of the maximum values described above. For example, the temperature can be from 400° C. to 2000° C. (e.g., from 400° C. to 1200° C., from 1200° C. to 2000° C., from 400° C. to 600° C., from 600° C. to 800° C., from 800° C. to 1000° C., from 1000° C. to 1200° C., from 1200° C. to 1400° C., from 1400° C. o 1600° C., from 1600° C. to 1800° C., from 1800° C. to 2000° C., from 500° C. to 2000° C., from 400° C. to 1900° C., or from 500° C. to 1900° C.).

In some examples, the substrate comprises GaN, and the etchant comprises Ga. In some examples, the substrate comprises Wurtzite Ga-polar or N-polar GaN.

In some examples, the substrate comprises AlN, and the etchant comprises Al.

In some examples, the method does not cause any other substantial damage to the substrate (e.g., substantially no damage to any subsurface of the substrate).

In some examples, the method further comprises repeating any of the methods disclosed herein to thereby etch another layer. In some examples, the methods further comprising selecting the number of cycles the method is repeated to thereby selectively etch a desired thickness of the substrate.

In some examples, the methods can further include etching lateral sidewalls.

Also disclosed herein are methods for damage-free etching of GaN and AlGaN/AlN by alternating thermal/plasma oxidation and etching using Ga flux and Al flux respectively in the ultra-high vacuum environment, for example wherein the method comprises any of the methods disclosed herein.

Also disclosed herein are methods for monolayer etching of GaN/AlGaN/AlN by using successive cycles of thermal/plasma oxidation and Ga and Al flux exposure respectively, for example wherein the method comprises any of the methods disclosed herein.

Also disclosed herein are methods for fabricating sub-micron 3D structures in GaN/AlGaN/AlN like fins, trenches, and nanopillar with vertical sidewalls for GaN/AlGaN/AlN-based devices, for example wherein the method comprises any of the methods disclosed herein.

Also disclosed herein are methods to obtain a controlled etch depth by using AlₓGa₁₋ₓN as an etch stop layer for Ga flux etching to etch only GaN films, for example wherein the method comprises any of the methods disclosed herein.

Also disclosed herein are methods to obtain a precise etch depth as the etch depth can be directly controlled by number of cycles, for example wherein the method comprises any of the methods disclosed herein.

### Patterned Substrates, Devices, and Methods of Use

Also disclosed herein are patterned substates made by any of the methods disclosed herein.

In some examples, the patterned substrate comprises a set of features extending from a surface of a substrate, and integrally formed therewith. In some examples, the set of features comprise sub-micron 3D structures. In some examples, the set of features have substantially vertical sidewalls. In some examples, the set of features comprises fins, trenches, pillars, or a combination thereof. In some examples, the patterned substrate has a regrowth pattern.

Also disclosed herein are methods of use of any of the patterned substrates disclosed herein. For example, the method can comprise using the patterned substrate in a device or an article of manufacture.

In some examples, the method comprises using the patterned substrate in an electronic device, an optical device, a photonic device, an optoelectronic device, or a combination thereof. In some examples, the method comprises using the patterned substrate in an energy storage device. In some examples, the method comprises using the patterned substrate in a power device. In some examples, the method comprises using the patterned substrate in a diode. In some examples, the method comprises using the patterned substrate in a memory device.

Also disclosed herein are devices or articles of manufacture comprising any of the patterned substrates disclosed herein.

In some examples, the device or article comprises an electronic device, an optical device, a photonic device, an optoelectronic device, or a combination thereof. In some examples, the device or article comprises an energy storage device. In some examples, the device or article comprises a power device. In some examples, the device or article comprises a diode. In some examples, the device or article comprises a memory device.

A number of embodiments of the invention have been described. Nevertheless, it will be understood that various modifications may be made without departing from the spirit and scope of the invention. Accordingly, other embodiments are within the scope of the following claims.

The examples below are intended to further illustrate certain aspects of the devices and methods described herein, and are not intended to limit the scope of the claims.

### EXAMPLES

The following examples are set forth below to illustrate the methods and results according to the disclosed subject matter. These examples are not intended to be inclusive of all aspects of the subject matter disclosed herein, but rather to illustrate representative methods and results. These examples are not intended to exclude equivalents and variations of the present invention which are apparent to one skilled in the art.

Efforts have been made to ensure accuracy with respect to numbers (e.g., amounts, temperature, etc.) but some errors and deviations should be accounted for. Unless indicated otherwise, parts are parts by weight, temperature is in ° C. or is at ambient temperature, and pressure is at or near atmospheric. There are numerous variations and combinations of measurement conditions, e.g., component concentrations, temperatures, pressures and other measurement ranges and conditions that can be used to optimize the described process.

### Example 1—Monolayer Etching of Wurtzite GaN/AlGaN/AlN Using Cyclic O₂ Plasma and Atomic Ga/Al Flux Exposure

Introduction: The demand for Gallium nitride (GaN)-based semiconductor electronic devices has been on the rise due to their increased efficiency in high power and micro-LED applications. The increased carrier mobility and breakdown electric field of GaN can be leveraged to produce electronic systems with size, weight, and power (SWaP) benefits over standard Si/SiC microelectronics. However, the fabrication of GaN-based devices often requires the selective removal of material through an etching process. Standard wet etching processes can leave the etched surface with unwanted impurities and are difficult to control precisely. In contrast, dry etching processes using reactive ion etching can provide better process control. However, the bombardment of the material with ions results in subsurface damage and roughened surface morphology that can negatively impact device performance. Other drawbacks include the formation of angled sidewalls and imprecise etch depths, making it difficult to produce highly scaled features. Additionally, the quality of any regrowth material on the etched surface is degraded due to plasma damage. Herein, a damage-free monolayer etching process using atomic Ga beam flux and an activated oxygen source in an ultra-high vacuum environment is presented. Using this method, 3D structures like fins, nanopillars, and regrowth patterns can be fabricated with vertical sidewalls and no damage to the semiconductor.

Method description: Previous reports have observed and detailed the thermal oxidation of GaN into its native oxide GaOₓ [1, 2]. The oxidized GaN layer can range from monolayers to hundreds of nanometers depending on the temperature, ambient atmosphere, and duration of the process. This oxidized GaN layer can be subsequently etched through exposure of the Ga₂O₃ to atomic Ga flux in an ultrahigh vacuum environment [3]. For the first time, this oxidation of GaN into Ga₂O₃ is leveraged to demonstrate a purely chemical, damage-free monolayer etching method to controllably etch the patterned GaN surface.

The etching of the GaN layer can be described by the following reactions:

First, the GaN forms a thin layer of its native oxide, Ga₂O₃ when exposed to the active oxygen (in this case a plasma source) according to the expression:

$$GaN ( s ) + \frac{5}{4} {O}_{2} ( g ) \to \frac{1}{2} {Ga}_{2} {O}_{3} ( s ) + NO ( g )$$

The thickness of this layer is limited by the diffusion of reactive oxygen through the Ga₂O₃ and GaN layer.

Once the Ga₂O₃ layer is formed, the exposed Ga₂O₃ layer is subjected to atomic Ga flux. A gallium suboxide is then formed according to the expression:

$$4 Ga ( s ) + {Ga}_{2} {O}_{3} ( s ) \to 3 {Ga}_{2} O ( g ) \qquad [ 4 ]$$

The suboxide Ga₂O readily desorbs from the surface, effectively etching the Ga₂O₃ layer [3] away to re-expose the GaN underneath. These two reactions can be repeated cyclically to etch GaN in a damage-free, purely chemical method with precise control.

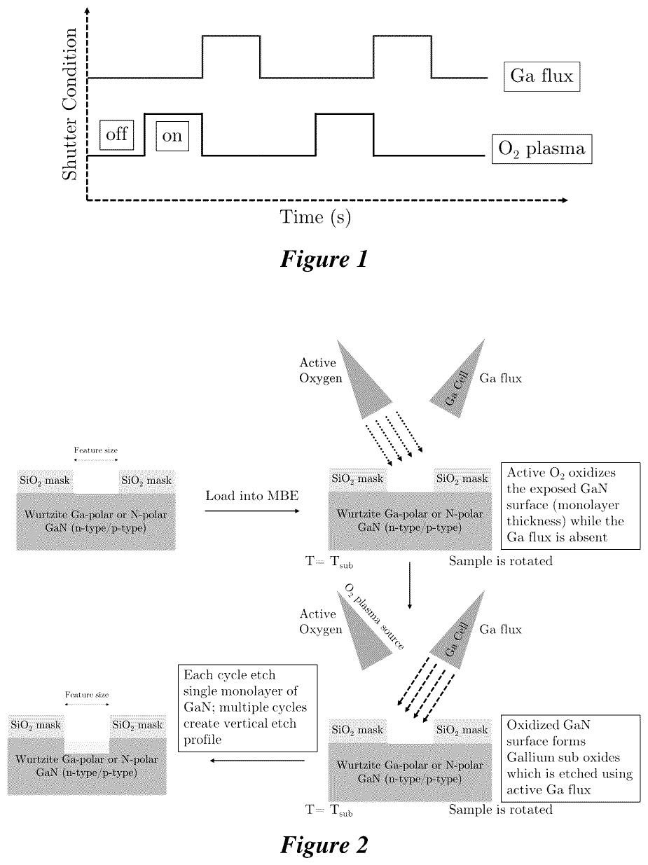

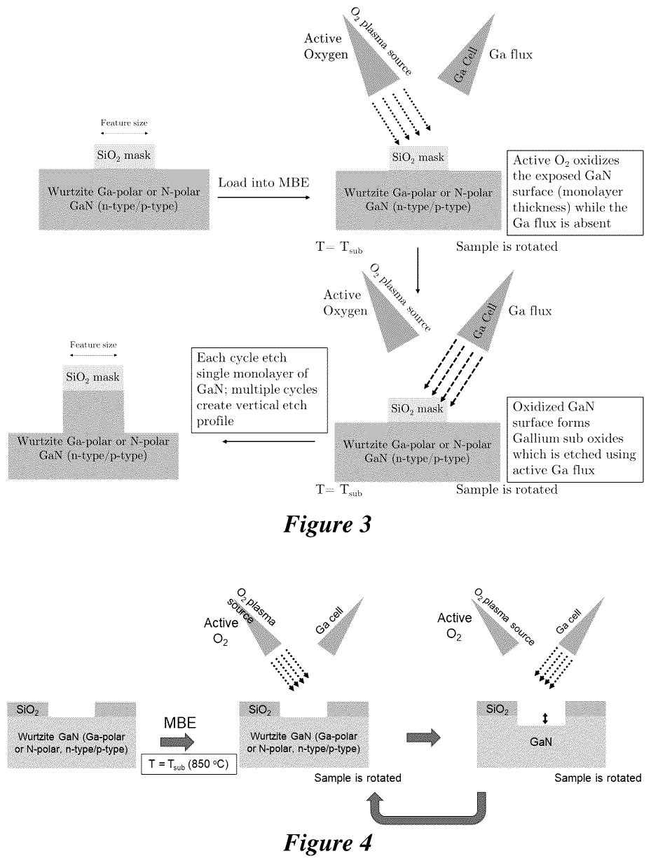

In practice, the process begins with patterning the GaN surface with an SiO₂ hard mask (shown in FIG. 2, FIG. 3). The patterned sample is then loaded into an ultra-high vacuum environment with a Gallium Knudsen effusion cell and an O₂ plasma source in which the high purity oxygen gas flow is controlled and adjusted by a mass flow controller (MFC). The sample is heated to at least 700° C. and is rotated at a small RPM to maintain etch uniformity across the sample. Active oxygen is generated by a radio frequency tuned plasma source and controllably exposed to the GaN surface by use of a mechanical shutter. The oxygen source is closed off and then the sample is subjected to a flux of gallium until the layer of Ga₂O₃ has been etched away. The sample is kept at high temperature for a period of time after the oxygen and Ga sources are closed off, allowing for any excess Ga atoms to desorb from the surface. This process results in monolayer etching in each cycle, and this cycle can be repeated to precisely achieve the desired etch depth. The timing diagram showing the shutter control for Ga flux and O₂ plasma source is shown in FIG. 1. The chamber maintains a high vacuum of 8×10⁻⁶ torr during the entire process. Additionally, using similar process AlGaN alloys can be etched at a sufficiently high temperature where Al can react with O to form Aluminum suboxides which can be etched using Al flux from the effusion cell.

### REFERENCES

[1] Oon, Hooi Shy, and Kuan Yew Cheong. “Recent development of gallium oxide thin film on GaN.” Materials science in semiconductor processing 16.5 (2013): 1217-1231.
[2] Yamada, Takahiro, et al. “Comprehensive study on initial thermal oxidation of GaN (0001) surface and subsequent oxide growth in dry oxygen ambient.” Journal of applied physics 121.3 (2017): 035303.
[3] Kalarickal, Nidhin Kurian, et al. “Planar and three-dimensional damage-free etching of β-Ga2O3 using atomic gallium flux.” Applied Physics Letters 119.12 (2021).
[4] Vogt, Patrick, and Oliver Bierwagen. “The competing oxide and sub-oxide formation in metal-oxide molecular beam epitaxy.” Applied Physics Letters 106.8 (2015): 081910.

### Example 2

Described herein are methods for damage-free etching of GaN and AlGaN/AlN by alternating thermal/plasma oxidation and etching using Ga flux and Al flux respectively in the ultra-high vacuum environment.

Described herein are methods for monolayer etching of GaN/AlGaN/AlN by using successive cycles of thermal/plasma oxidation and Ga and Al flux exposure respectively.

Described herein are methods for fabricating sub-micron 3D structures in GaN/AlGaN/AlN like fins, trenches, and nanopillar with vertical sidewalls for GaN/AlGaN/AlN-based devices.

Described herein are methods to obtain a controlled etch depth by using AlₓGa₁₋ₓN as an etch stop layer for Ga flux etching to etch only GaN films.

Described herein are methods to obtain a precise etch depth as the etch depth can be directly controlled by number of cycles.

### Example 3—Damage Free p-GaN Etch: MBE

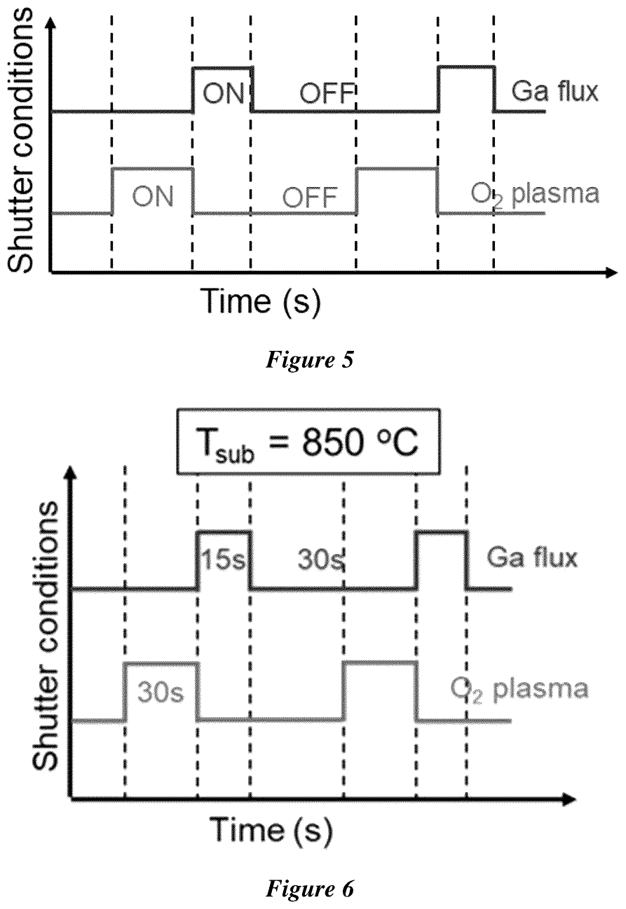

Described herein are methods for damage-free etching of p-GaN in MBE. A example schematic of the process is shown in FIG. 4 and FIG. 5.

The method comprises GaN surface oxidation using active O₂:

$$GaN ( s ) + \frac{5}{4} {O}_{2} ( g ) \to \frac{1}{2} {Ga}_{2} {O}_{3} ( s ) + NO ( g )$$

The method further comprises Ga suboxide formation on oxidized GaN surface:

$$4 Ga ( s ) + {Ga}_{2} {O}_{3} ( s ) \to 3 {Ga}_{2} O ( g )$$

The method further comprises Ga₂O suboxide desorption from the surface.

Single monolayer GaN etch for each cycle, and multiple cycles can be repeated to create a vertical etch profile.

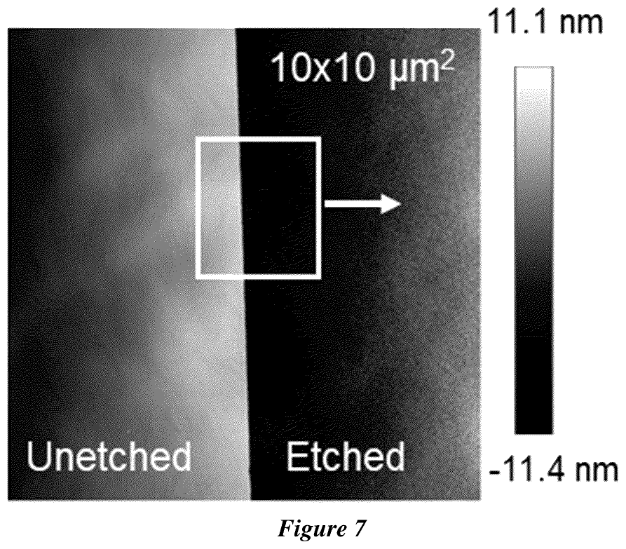

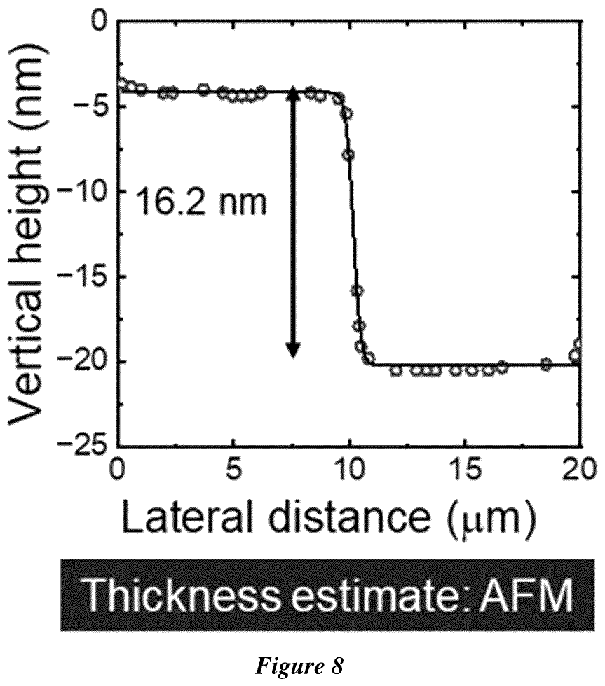

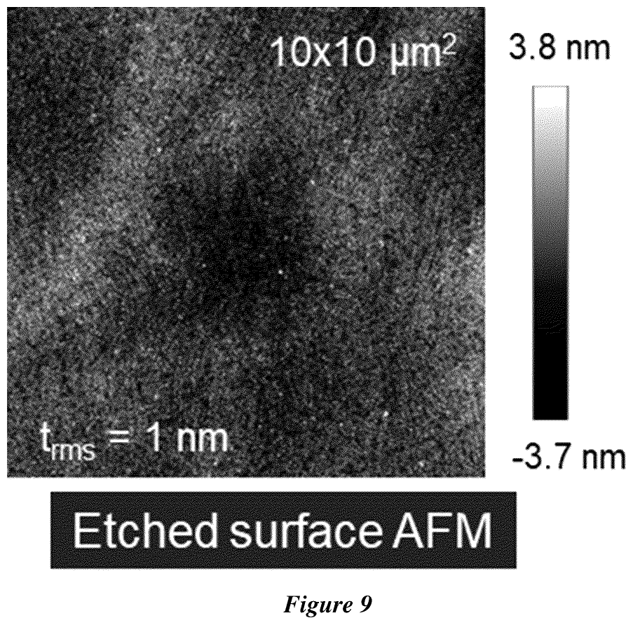

Results are shown in FIG. 6-FIG. 9. 16.2 nm GaN was etched in 72 cycles. Each cycle comprised: 15 s Ga exposure, 30 secs O₂ plasma exposure, and 30 s Ga desorption. MBE etch conditions were optimized for smooth surface etch. Similar trms (˜1 nm) for the etched and non-etched surface. The etched surface had a slight grainy morphology due to oxygen exposure and formation of Ga sub-oxides. Further etch rate and surface optimization can, for example, include using Ga polishing/TMAH treatment.

### Exemplary Aspects

In view of the described compositions, devices, systems, and methods, herein below are described certain more particularly described aspects of the inventions. The particularly recited aspects should not, however, be interpreted to have any limiting effect on any different claims containing different or more general teachings described herein or that the “particular” aspects are somehow limited in some way other than the inherent meanings of the language and formulas literally used therein.

Example 1: A method comprising: oxidizing at least a portion of a surface of a substrate comprising a group III-V compound, thereby forming an oxidized layer at said portion of the surface; and etching the oxidized layer by exposing the oxidized layer to an etchant; wherein: the group III-V compound comprises one or more group III elements (e.g., Al, Ga, In, B, Sc, Y, or a combination thereof) and a group V element (e.g., N, As, or Sb); the etchant comprises at least one of the group III elements; and the etchant removes oxides by the etchant reacting with the oxide to form a suboxide, which desorbs from the surface.

Example 2: The method of any examples herein, particularly example 1, wherein the one or more group III elements are selected from the group consisting of Al, Ga, In, B, Sc, Y, and combinations thereof; and the group V element is selected from the group consisting of N, As, and Sb.

Example 3: The method of any examples herein, particularly example 1 or example 2, wherein the group III-V compound comprises InₓGa₁₋ₓN, AlₓGa₁₋ₓN, ScₓGa₁₋ₓN, YₓGa₁₋ₓN, AlₓGa₁₋ₓAs, InₓGa₁₋ₓAs, AlₓGa₁₋ₓSb, InₓGa₁₋ₓSb, or a combination thereof, wherein each x independently is from 0 to 1.

Example 4: The method of any examples herein, particularly examples 1-3, wherein the group III-V compound comprises GaN, InN, AlN, ScN, YN, GaAs, AlAs, InAs, GaSb, InSb, AlSb, or a combination thereof.

Example 5: The method of any examples herein, particularly examples 1-4, wherein the group III-V compound comprises AlₓGa₁₋ₓN, wherein x is from 0 to 1.

Example 6: The method of any examples herein, particularly examples 1-5, wherein the group III-V compound comprises AlₓGa₁₋ₓN, and the etchant comprises Al, Ga, or a combination thereof.

Example 7: A method comprising: oxidizing at least a portion of a surface of a substrate comprising AlₓGa₁₋ₓN, thereby forming an oxidized layer at said portion of the surface; and etching the oxidized layer by exposing the oxidized layer to an etchant; wherein the etchant comprises Al, Ga, or a combination thereof; and wherein the etchant removes oxides by the etchant reacting with the oxide comprising the etchant to form a suboxide, which desorbs from the surface.

Example 8: The method of any examples herein, particularly example 7, wherein: when x=1, the etchant comprises Al; when x=0, the etchant comprises Ga; and when 0<x<1, the etchant comprises Al, Ga, or a combination thereof.

Example 9: A method comprising: oxidizing at least a portion of a surface of a substrate comprising AlₓGa₁₋ₓN, thereby forming an oxidized layer at said portion of the surface; and etching the oxidized layer by exposing the oxidized layer to an etchant; wherein: when x=1, the etchant comprises Al; when x=0, the etchant comprises Ga; and when 0<x<1, the etchant comprises Al, Ga, or a combination thereof; wherein the etchant removes oxides comprising said etchant (e.g., Al etches aluminum oxides, Ga etches gallium oxides) by the etchant reacting with the oxide comprising the etchant to form a suboxide, which desorbs from the surface.

Example 10: The method of any examples herein, particularly examples 1-9, wherein the oxidized layer comprises an oxidized monolayer.

Example 11: The method of any examples herein, particularly examples 1-10, wherein oxidizing said portion comprises thermal oxidation, plasma oxidation, exposing said portion to an oxidizing agent (e.g., water, active oxygen, hydrogen peroxide, etc.), or a combination thereof.

Example 12: The method of any examples herein, particularly examples 1-11, wherein oxidizing said portion comprises thermal oxidation, plasma oxidation, or a combination thereof.

Example 13: The method of any examples herein, particularly examples 1-12, wherein the portion of the substrate is oxidized for a first amount of time.

Example 14: The method of any examples herein, particularly example 13, wherein the first amount of time is from 1 millisecond (ms) to 10 hours.

Example 15: The method of any examples herein, particularly examples 1-14, wherein the oxidized layer is exposed to the etchant for a second amount of time.

Example 16: The method of any examples herein, particularly example 15, wherein the second amount of time is from millisecond (ms) to 10 hours.

Example 17: The method of any examples herein, particularly examples 13-16, wherein the first amount of time and/or the second amount of time are controlled, for example, by opening and/or closing one or more shutters.

Example 18: The method of any examples herein, particularly examples 13-17, wherein the first amount of time and/or the second amount of time are selected to achieve a desired result, such as a desired etch depth.

Example 19: The method of any examples herein, particularly examples 1-18, wherein exposing the oxidized layer to the etchant comprises exposing the oxidized layer to a compound comprising the etchant, an atomic flux of the etchant, or a combination thereof.

Example 20: The method of any examples herein, particularly examples 1-19, wherein exposing the oxidized layer to the etchant comprises exposing the oxidized layer to a compound comprising the etchant.

Example 21: The method of any examples herein, particularly example 19 or example 20, wherein the compound comprising the etchant undergoes decomposition to deposit the etchant on the oxidized layer.

Example 22: The method of any examples herein, particularly examples 1-21, wherein exposing the oxidized layer to the etchant comprises using an atomic flux of the etchant (e.g., an atomic flux of Al and/or Ga).

Example 23: The method of any examples herein, particularly examples 1-22, wherein the substrate further comprises a mask disposed on the surface thereof, wherein the mask covers a first portion of the surface of the substrate and does not cover a second portion of the surface of the substrate, wherein the second portion of the substrate is the portion oxidized by the method.

Example 24: The method of any examples herein, particularly example 23, wherein the method further comprises disposing the mask on the surface of the substrate.

Example 25: The method of any examples herein, particularly examples 1-24, wherein the substrate further comprise an etch stop layer, the etch stop layer comprising a composition that is not susceptible to etching by the etchant.

Example 26: The method of any examples herein, particularly examples 1-25, wherein the method is performed in an ultra-high vacuum environment.

Example 27: The method of any examples herein, particularly examples 1-26, wherein the method further comprises rotating the substrate during the methods, for example to improve uniformity of the oxidation and/or etching.

Example 28: The method of any examples herein, particularly examples 1-27, wherein the method further comprises heating the substrate at a temperature during the etching, wherein the temperature is selected to improve the etching.

Example 29: The method of any examples herein, particularly example 28, wherein the temperature is from 400° C. to 2000° C.

Example 30: The method of any examples herein, particularly examples 1-29, wherein the substrate comprises GaN, and the etchant comprises Ga.

Example 31: The method of any examples herein, particularly example 30, wherein the substrate comprises Wurtzite Ga-polar or N-polar GaN.

Example 32: The method of any examples herein, particularly examples 1-29, wherein the substrate comprises AlN, and the etchant comprises Al.

Example 33: The method of any examples herein, particularly examples 1-32, wherein the method does not cause any other substantial damage to the substrate (e.g., substantially no damage to any subsurface of the substrate).

Example 34: The method of any examples herein, particularly examples 1-33, wherein the method further comprises repeating the method of any one of claims 1-33 to thereby etch another layer.

Example 35: The method of any examples herein, particularly example 34, further comprising selecting the number of cycles the method is repeated to thereby selectively etch a desired thickness of the substrate.

Example 36: The method of any examples herein, particularly examples 1-35, wherein the method further includes etching lateral sidewalls.

Example 37: A method for damage-free etching of GaN and AlGaN/AlN by alternating thermal/plasma oxidation and etching using Ga flux and Al flux respectively in the ultra-high vacuum environment, for example wherein the method comprises the method of any examples herein, particularly examples 1-36.

Example 38: A method for monolayer etching of GaN/AlGaN/AlN by using successive cycles of thermal/plasma oxidation and Ga and Al flux exposure respectively, for example wherein the method comprises the method of any examples herein, particularly examples 1-37.

Example 39: A method for fabricating sub-micron 3D structures in GaN/AlGaN/AlN like fins, trenches, and nanopillar with vertical sidewalls for GaN/AlGaN/AlN-based devices, for example wherein the method comprises the method of any examples herein, particularly examples 1-38.

Example 40: A method to obtain a controlled etch depth by using AlₓGa₁₋ₓN as an etch stop layer for Ga flux etching to etch only GaN films, for example wherein the method comprises the method of any examples herein, particularly examples 1-39.

Example 41: A method to obtain a precise etch depth as the etch depth can be directly controlled by number of cycles, for example wherein the method comprises the method of any examples herein, particularly examples 1-40.

Example 42: A patterned substrate made by the method of any examples herein, particularly examples 1-41.

Example 43: The patterned substrate of any examples herein, particularly example 42, wherein the patterned substrate comprises a set of features extending from a surface of a substrate, and integrally formed therewith.

Example 44: The patterned substrate of any examples herein, particularly example 42 or example 43, wherein the set of features comprise sub-micron 3D structures.

Example 45: The patterned substrate of any examples herein, particularly examples 42-44, wherein the set of features have substantially vertical sidewalls.

Example 46: The patterned substrate of any examples herein, particularly examples 42-45, wherein the set of features comprises fins, trenches, pillars, or a combination thereof.

Example 47: The patterned substrate of any examples herein, particularly examples 42-46, wherein the patterned substrate has a regrowth pattern.

Example 48: A method of use of the patterned substrate of any examples herein, particularly examples 42-47.

Example 49: The method of any examples herein, particularly example 48, wherein the method comprises using the patterned substrate in an electronic device, an optical device, a photonic device, an optoelectronic device, or a combination thereof.

Example 50: The method of any examples herein, particularly example 48 or example 49, wherein the method comprises using the patterned substrate in an energy storage device.

Example 51: The method of any examples herein, particularly examples 48-50, wherein the method comprises using the patterned substrate in a power device.

Example 52: The method of any examples herein, particularly examples 48-51, wherein the method comprises using the patterned substrate in a diode.

Example 53: The method of any examples herein, particularly examples 48-52, wherein the method comprises using the patterned substrate in a memory device.

Example 54: A device or article of manufacture comprising the patterned substrate of any examples herein, particularly examples 42-47.

Example 55: The device or article of any examples herein, particularly example 54, wherein the device or article comprises an electronic device, an optical device, a photonic device, an optoelectronic device, or a combination thereof.

Example 56: The device or article of any examples herein, particularly example 54 or example 55, wherein the device or article comprises an energy storage device.

Example 57: The device or article of any examples herein, particularly examples 54-56, wherein the device or article comprises a power device.

Example 58: The device or article of any examples herein, particularly examples 54-57, wherein the device or article comprises a diode.

Example 59: The device or article of any examples herein, particularly examples 54-58, wherein the device or article comprises a memory device.

Other advantages which are obvious and which are inherent to the invention will be evident to one skilled in the art. It will be understood that certain features and sub-combinations are of utility and may be employed without reference to other features and sub-combinations. This is contemplated by and is within the scope of the claims. Since many possible embodiments may be made of the invention without departing from the scope thereof, it is to be understood that all matter herein set forth or shown in the accompanying drawings is to be interpreted as illustrative and not in a limiting sense.

The methods of the appended claims are not limited in scope by the specific methods described herein, which are intended as illustrations of a few aspects of the claims and any methods that are functionally equivalent are intended to fall within the scope of the claims. Various modifications of the methods in addition to those shown and described herein are intended to fall within the scope of the appended claims. Further, while only certain representative method steps disclosed herein are specifically described, other combinations of the method steps also are intended to fall within the scope of the appended claims, even if not specifically recited. Thus, a combination of steps, elements, components, or constituents may be explicitly mentioned herein or less, however, other combinations of steps, elements, components, and constituents are included, even though not explicitly stated.

What is claimed is:

1. A method comprising:
oxidizing at least a portion of a surface of a substrate comprising a group III-V compound, thereby forming an oxidized layer at said portion of the surface; and
etching the oxidized layer by exposing the oxidized layer to an etchant;
wherein:
the group III-V compound comprises one or more group III elements and a group V element;
the etchant comprises at least one of the group III elements; and
the etchant removes oxides by the etchant reacting with the oxide to form a suboxide, which desorbs from the surface.

2. The method of claim 1, wherein the one or more group III elements are selected from the group consisting of Al, Ga, In, B, Sc, Y, and combinations thereof; and the group V element is selected from the group consisting of N, As, and Sb.

3. The method of claim 1, wherein the group III-V compound comprises InₓGa₁₋ₓN, AlₓGa₁₋ₓ N, Scₓ Ga₁₋ₓN, YₓGa₁₋ₓN, AlₓGa₁₋ₓAs, InₓGa₁₋ₓAs, AlₓGa₁₋ₓSb, InₓGa₁₋ₓSb, or a combination thereof, wherein each x independently is from 0 to 1.

4. The method of claim 1, wherein the group III-V compound comprises GaN, InN, AlN, ScN, YN, GaAs, AlAs, InAs, GaSb, InSb, AlSb, or a combination thereof.

5. The method of claim 1, wherein the group III-V compound comprises AlₓGa₁₋ₓN, wherein x is from 0 to 1.

6. The method of claim 1, wherein the group III-V compound comprises AlₓGa₁₋ₓN, wherein x is from 0 to 1, and the etchant comprises Al, Ga, or a combination thereof.

7. The method of claim 6, wherein:
when x=1, the etchant comprises Al;
when x=0, the etchant comprises Ga; and
when 0<x<1, the etchant comprises Al, Ga, or a combination thereof.

8. The method of claim 1, wherein the oxidized layer comprises an oxidized monolayer.

9. The method of claim 1, wherein oxidizing said portion comprises thermal oxidation, plasma oxidation, exposing said portion to an oxidizing agent, or a combination thereof.

10. The method of claim 1, wherein exposing the oxidized layer to the etchant comprises exposing the oxidized layer to a compound comprising the etchant, an atomic flux of the etchant, or a combination thereof.

11. The method of claim 1, wherein the substrate further comprises a mask disposed on the surface thereof, wherein the mask covers a first portion of the surface of the substrate and does not cover a second portion of the surface of the substrate, wherein the second portion of the substrate is the portion oxidized by the method.

12. The method of claim 1, wherein the substrate further comprise an etch stop layer, the etch stop layer comprising a composition that is not susceptible to etching by the etchant.

13. The method of claim 1, wherein the method further comprises rotating the substrate during the methods.

14. The method of claim 1, wherein the method further comprises heating the substrate at a temperature during the etching.

15. The method of claim 1, wherein the substrate comprises GaN, and the etchant comprises Ga.

16. The method of claim 1, wherein the substrate comprises AlN, and the etchant comprises Al.

17. The method of claim 1, wherein the method does not cause any other substantial damage to the substrate.

18. The method of claim 1, wherein the method further comprises repeating the method of claim 1 to thereby etch another layer.

19. The method of claim 18, further comprising selecting the number of cycles the method is repeated to thereby selectively etch a desired thickness of the substrate.

20. A patterned substrate made by the method of claim 1.
